(19) United States
(12) Patent Application Publication
(10) Pub. No.: US 2026/0075811 A1
(43) Pub. Date: Mar. 12, 2026

(54) SEMICONDUCTOR MEMORY DEVICES

(71) Applicant: SAMSUNG ELECTRONICS CO., LTD., Suwon-si (KR)

(72) Inventors: Changkyu Kim, Suwon-si (KR); Dongjun Lee, Suwon-si (KR)

(73) Assignee: SAMSUNG ELECTRONICS CO., LTD., Suwon-si (KR)

(21) Appl. No.: 19/324,549

(22) Filed: Sep. 10, 2025

(30) Foreign Application Priority Data
Sep. 10, 2024 (KR) 10-2024-0123430

(51) Int. Cl. H10B 12/00; G11C 5/06; H01L 23/00; H01L 25/18; H10D 80/30

(52) U.S. Cl. CPC H10B 12/488; G11C 5/063; H10B 12/315; H10B 12/482; H10B 12/50; H10D 80/30; H10W 90/00; H10W 90/792

(57) ABSTRACT

Provided is a semiconductor memory device including: a first substrate comprising a cell array region and a first scribe lane region surrounding the cell array region in a plan view; a memory cell array on the cell array region; a dam structure on the first scribe lane region, the dam structure surrounding the memory cell array in a plan view and the dam structure comprising a first sidewall facing the memory cell array and a second sidewall opposite the first sidewall; a first dam isolation insulating layer between the memory cell array and the first sidewall; a second dam isolation insulating layer on the second sidewall; and a dummy stack on the first scribe lane region of the first substrate, the dummy stack comprising a plurality of first semiconductor layers and a plurality of second semiconductor layers alternately stacked in a vertical direction.

### CROSS-REFERENCE TO RELATED APPLICATION

This application is based on and claims priority to Korean Patent Application No. 10-2024-0123430, filed on Sep. 10, 2024, in the Korean Intellectual Property Office, the disclosure of which is incorporated by reference herein in its entirety.

### BACKGROUND

### 1. Field

The disclosure relates to a semiconductor memory device, and more particularly, to a three-dimensional semiconductor memory device.

### 2. Description of Related Art

High-capacity semiconductor memory devices are required as electronic products are required to be miniaturized, multifunctional, and high-performance, and increased integration is required to provide high-capacity semiconductor memory devices. A three-dimensional semiconductor memory device has been proposed to increase memory capacity by stacking a plurality of memory cells in a vertical direction on a substrate.

### SUMMARY

Provided is a three-dimensional semiconductor memory device capable of preventing moisture or water from penetrating into a cell array region and preventing cracks from propagating.

According to an aspect of the disclosure, a semiconductor memory device includes: a first substrate including a cell array region and a first scribe lane region surrounding the cell array region in a plan view; a memory cell array on the cell array region; a dam structure on the first scribe lane region, wherein the dam structure surrounds the memory cell array in a plan view and the dam structure includes a first sidewall facing the memory cell array and a second sidewall opposite the first sidewall; a first dam isolation insulating layer between the memory cell array and the first sidewall of the dam structure; a second dam isolation insulating layer on the second sidewall of the dam structure; and a dummy stack on the first scribe lane region of the first substrate, the dummy stack including a plurality of first semiconductor layers and a plurality of second semiconductor layers alternately stacked in a vertical direction.

According to an aspect of the disclosure, a semiconductor memory device includes: a memory cell array on a first substrate, the memory cell array including: a plurality of semiconductor patterns on the first substrate, wherein the plurality of semiconductor patterns are spaced apart from each other in a vertical direction, a bit line extending in the vertical direction on the first substrate and commonly connected to a first end of each of the plurality of semiconductor patterns, and a plurality of capacitors on the first substrate, wherein the plurality of capacitors are spaced apart from each other in the vertical direction, and are each connected to a second end of the plurality of semiconductor patterns, and wherein the second end of the plurality of semiconductor patterns is opposite to the first end of the plurality of semiconductor patterns; a dam structure on the first substrate, wherein the dam structure surrounds the memory cell array in a plan view; and a first dam isolation insulating layer between the memory cell array and the dam structure, wherein the first dam isolation insulating layer surrounds the memory cell array in a plan view.

According to an aspect of the disclosure, a semiconductor memory device includes: a first substrate including a cell array region and a first scribe lane region surrounding the cell array region in a plan view; a memory cell array on the cell array region, the memory cell array including: a plurality of semiconductor patterns on the first substrate, wherein the plurality of semiconductor patterns are vertically spaced apart from each other; a bit line extending in a vertical direction on the first substrate and commonly connected to a first end of each of the plurality of semiconductor patterns; and a plurality of capacitors on the first substrate, wherein the plurality of capacitors are spaced apart in the vertical direction, and are each connected to a second end of the plurality of semiconductor patterns, and wherein the second end of the plurality of semiconductor patterns is opposite to the first end of the plurality of semiconductor patterns; a dam structure on the first scribe lane region, wherein the dam structure surrounds the memory cell array in a plan view; a first dam isolation insulating layer between the memory cell array and the dam structure, wherein the first dam isolation insulating layer surrounds the memory cell array in a plan view; a second substrate at a higher vertical level than the memory cell array; a peripheral circuit on the second substrate; and a peripheral circuit dam on the second substrate and surrounding the peripheral circuit in a plan view.

### BRIEF DESCRIPTION OF THE DRAWINGS

The above and other aspects and features of certain embodiments of the present disclosure will be more apparent from the following description taken in conjunction with the accompanying drawings, in which:

FIG. 1 is a schematic perspective view of a semiconductor memory device according to one or more embodiments;

FIG. 2 is a circuit diagram illustrating a memory cell array arranged in the cell array region shown in FIG. 1;

FIG. 3 is a planar layout view of a first stack structure of a semiconductor memory device according to one or more embodiments;

FIG. 4 is a planar layout view of a second stack structure of a semiconductor memory device according to one or more embodiments;

FIG. 5 is a perspective view schematically illustrating a portion of a cell array region of the first stack structure of FIG. 3;

FIG. 6 is a cross-sectional view taken along a line A1-A1′ of FIG. 5;

FIG. 7 is a cross-sectional view taken along a line B1-B1′ of FIG. 5;

FIG. 8 is a cross-sectional view taken along a line C1-C1′ of FIGS. 3 and 4;

FIG. 9 is an enlarged view of a portion CX1 of FIG. 6;

FIG. 10 is a layout view illustrating an example of a word line pad included in a semiconductor memory device according to one or more embodiments;

FIG. 11 is a layout view illustrating a semiconductor memory device according to one or more embodiments;

FIG. 12 is a cross-sectional view along a line C1-C1′ of FIG. 11; and

FIGS. 13A, 13B, 13C, 14, 15A, 15B, 15C, 16A, 16B, 17A, 17B, 18, 19, 20A, 20B, 20C, 21A, 21B, and 21C are schematic diagrams illustrating a method of manufacturing a semiconductor memory device according to one or more embodiments.

### DETAILED DESCRIPTION

In the following description, like reference numerals refer to like elements throughout the specification.

It will be understood that when an element is referred to as being “connected” with or to another element, it can be directly or indirectly connected to the other element.

Also, when a part “includes” or “comprises” an element, unless there is a particular description contrary thereto, the part may further include other elements, not excluding the other elements.

Throughout the description, when a member is “on” another member, this includes not only when the member is in contact with the other member, but also when there is another member between the two members.

As used herein, the expressions “at least one of a, b or c” and “at least one of a, b and c” indicate “only a,” “only b,” “only c,” “both a and b,” “both a and c,” “both b and c,” and “all of a, b, and c.”

It will be understood that, although the terms “first”, “second”, “third”, etc., may be used herein to describe various elements, the disclosure should not be limited by these terms. These terms are only used to distinguish one element from another element.

As used herein, the singular forms “a,” “an” and “the” are intended to include the plural forms as well, unless the context clearly indicates otherwise.

With regard to any method or process described herein, an identification code may be used for the convenience of the description but is not intended to illustrate the order of each step or operation. Each step or operation may be implemented in an order different from the illustrated order unless the context clearly indicates otherwise. One or more steps or operations may be omitted unless the context of the disclosure clearly indicates otherwise.

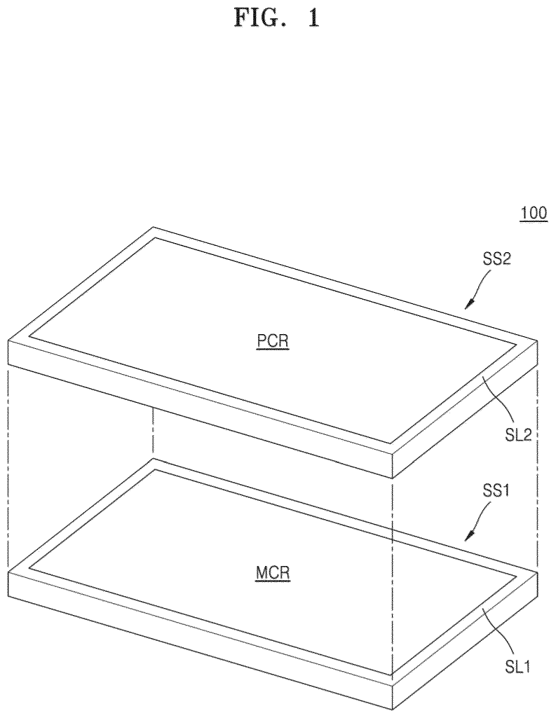

FIG. 1 is a schematic perspective view of a semiconductor memory device 100 according to one or more embodiments.

Referring to FIG. 1, a semiconductor memory device 100 may have a structure in which a first stack structure SS1 and a second stack structure SS2 are stacked in a vertical direction. For example, the first stack structure SS1 and the second stack structure SS2 may be arranged at different vertical levels. Although FIG. 1 illustrates a state in which the first stack structure SS1 and the second stack structure SS2 are separated for convenience of understanding, the semiconductor memory device 100 may have a structure in which a bottom surface of the second stack structure SS2 is attached to a top surface of the first stack structure SS1.

The first stack structure SS1 may include a cell array region MCR and a first scribe lane region SL1 surrounding the cell array region MCR in a plan view. The first scribe lane region SL1 may be an edge region of the first stack structure SS1, may be a region in which a wafer is cut to separate a plurality of cell array regions MCR formed on the wafer into individual chips, or may be a region between two adjacent cell array regions MCR.

The second stack structure SS2 may include a peripheral circuit region PCR and a second scribe lane region SL2 surrounding the peripheral circuit region PCR in a plan view. The second scribe lane region SL2 may be an edge region of the second stack structure SS2, may be a region in which a wafer is cut to separate a plurality of peripheral circuit regions PCR formed on the wafer into individual chips, or may be a region between two adjacent peripheral circuit regions PCR.

In one or more embodiments, the cell array region MCR may be a memory cell region of a dynamic random access memory (DRAM) device, and the peripheral circuit region PCR may be a core region or a peripheral circuit region of the DRAM device. For example, the peripheral circuit region PCR may include a peripheral circuit transistor for transmitting signals and/or power to a memory cell array included in the cell array region MCR. In one or more embodiments, the peripheral circuit transistor may constitute various circuits such as a command decoder, a control logic, an address buffer, a row decoder, a column decoder, a sense amplifier, and a data input/output circuit.

Although FIG. 1 illustrates an example case in which the peripheral circuit region PCR is arranged at a higher vertical level than the cell array region MCR (e.g., the peripheral circuit region PCR is arranged on the cell array region MCR). However, in one or more embodiments, the semiconductor memory device 100 may be inverted so that the cell array region MCR is positioned at a higher vertical level than the peripheral circuit region PCR.

In one or more embodiments, the peripheral circuit region PCR and the cell array region MCR may be formed on individual wafers, and then the peripheral circuit region PCR and the cell array region MCR may be attached to each other using a bonding pad. In other embodiments, a peripheral circuit region PCR may be first formed on a peripheral circuit wafer, and then a cell array region MCR may be formed on the peripheral circuit region PCR.

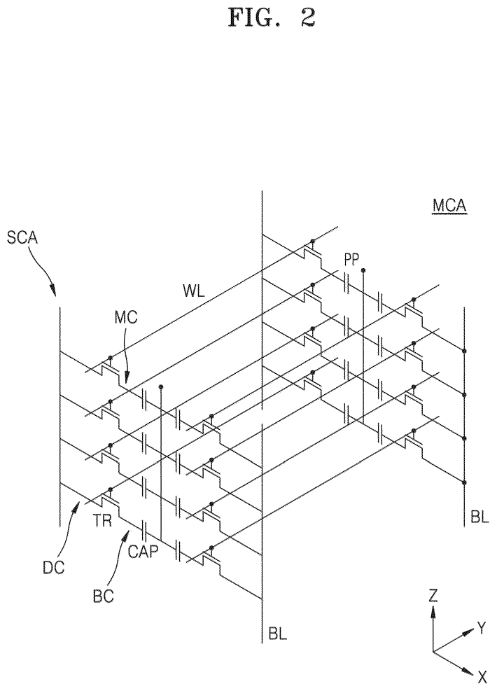

FIG. 2 is a circuit diagram illustrating a memory cell array MCA arranged in the cell array region MCR shown in FIG. 1.

Referring to FIG. 2, the memory cell array MCA may include a vertically stacked DRAM device. The memory cell array MCA may include a plurality of sub-cell arrays SCA, and the plurality of sub-cell arrays SCA may be arranged to be spaced apart from each other in a second horizontal direction Y.

Each sub-cell array SCA may include a plurality of bit lines BL, a plurality of word lines WL, and a plurality of memory cells MC. Each of the plurality of memory cells MC may include one cell transistor TR and one cell capacitor CAP connected thereto. Each of the plurality of memory cells MC may have a 1 transistor-1 capacitor (1T1C) structure. However, it should be understood that the disclosure is not limited to this structure, and various alternative or modified structures are contemplated.

The plurality of word lines WL may extend in the second horizontal direction Y and may be arranged to be spaced apart from each other in a first horizontal direction X and the vertical direction Z. The plurality of bit lines BL may extend in the vertical direction Z and may be arranged to be spaced apart from each other in the first horizontal direction X and the second horizontal direction Y. One cell transistor TR may be arranged between one word line WL and one bit line BL.

The gate of the cell transistor TR may be connected to the word line WL, and the source of the cell transistor TR may be connected to the bit line BL through a first contact DC. The cell transistor TR may be connected to the cell capacitor CAP through a second contact BC. The drain of the cell transistor TR may be connected to a first electrode of the cell capacitor CAP through the second contact BC, and a second electrode of the cell capacitor CAP may be connected to a plate electrode PP.

In one sub-cell array SCA, the plurality of cell transistors TR may be arranged at positions overlapping each other in the vertical direction Z. In one sub-cell array SCA, the plurality of cell capacitors CAP may be arranged at positions overlapping each other in the vertical direction Z. One cell transistor TR and one cell capacitor CAP may be arranged side by side at the same vertical level, and a plurality of memory cells MC each including one cell transistor TR and one cell capacitor CAP may be stacked in the vertical direction Z. The storage capacity of the sub-cell array SCA may vary depending on the number of memory cells MC stacked in the vertical direction Z (e.g., the number of the cell capacitors CAP).

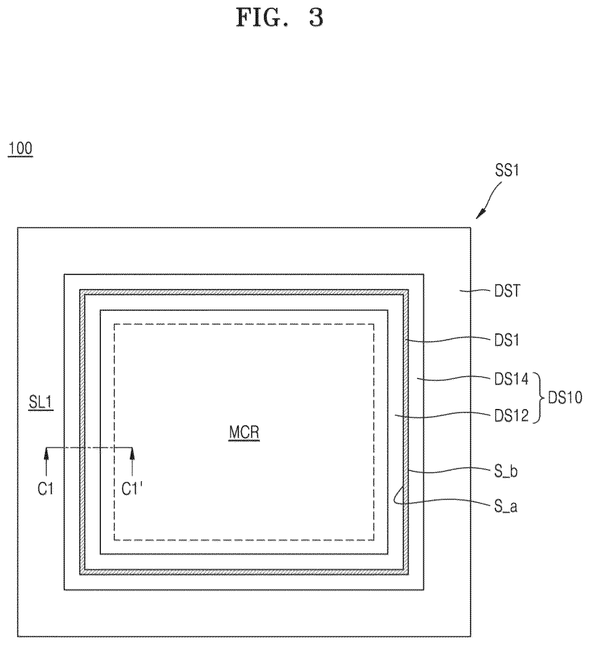

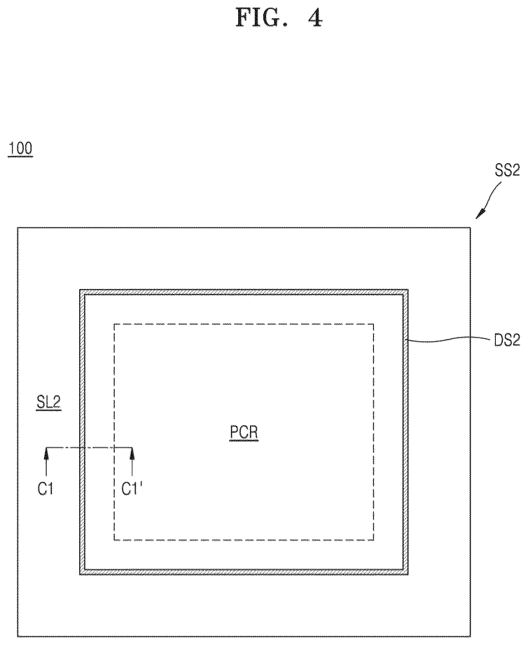

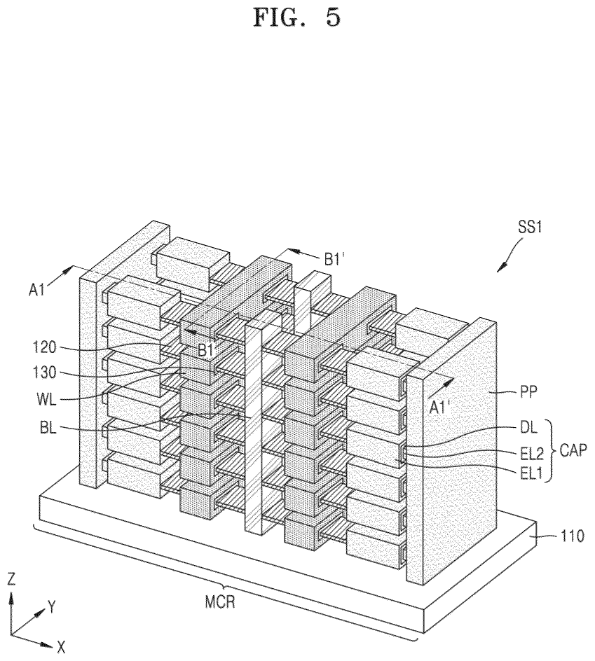

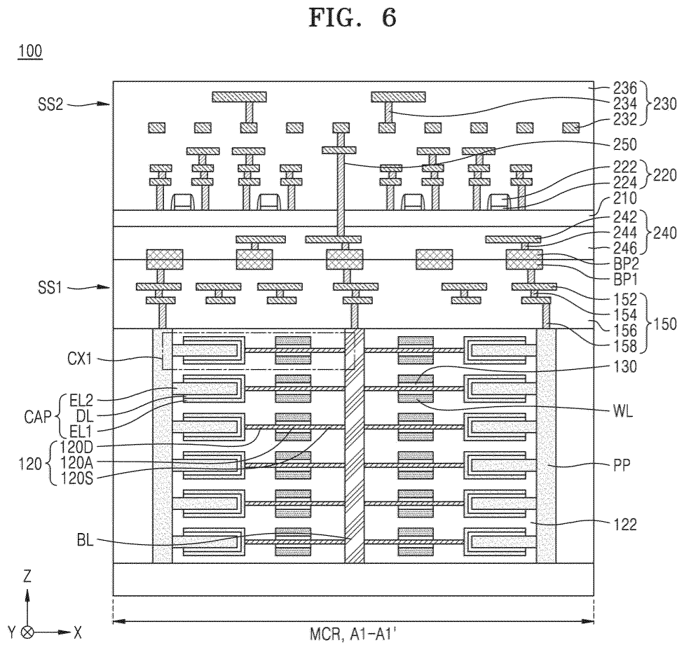

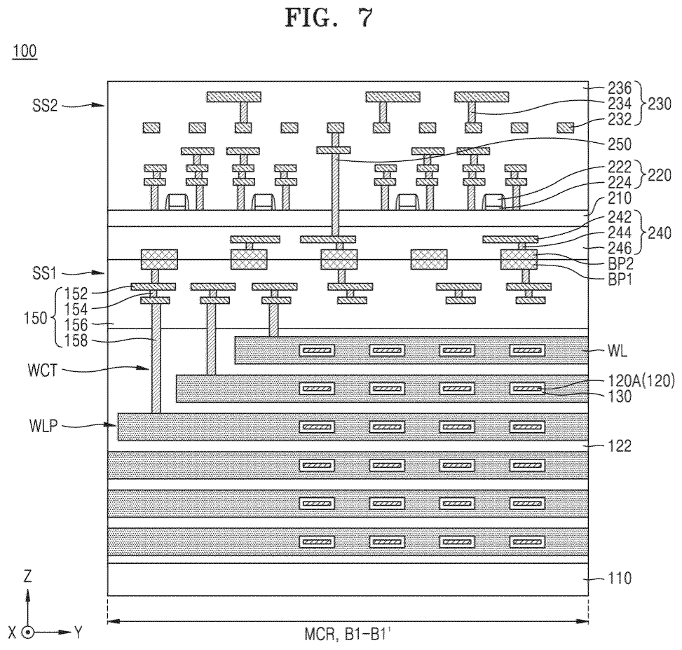

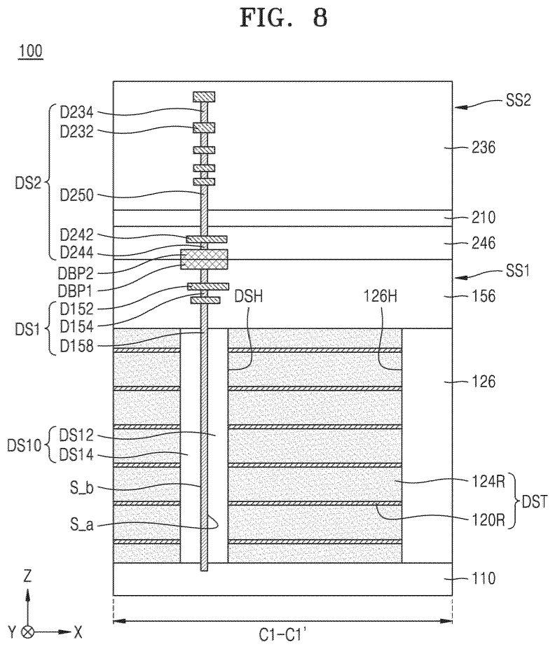

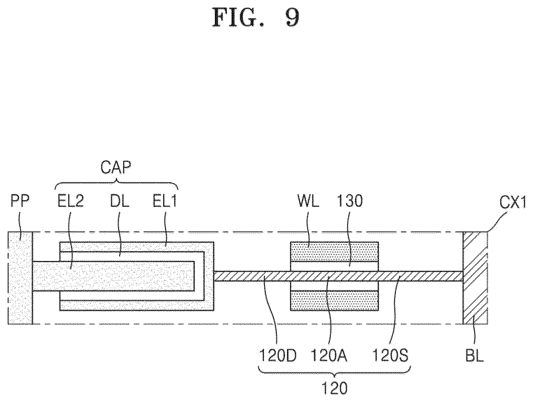

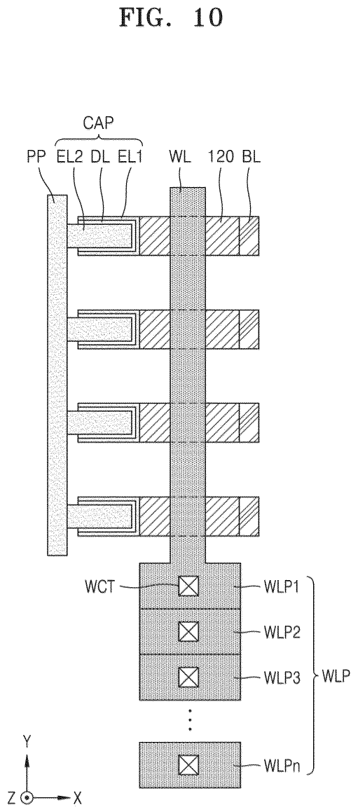

FIG. 3 is a planar layout view of a first stack structure SS1 of a semiconductor memory device 100 according to one or more embodiments. FIG. 4 is a planar layout view of a second stack structure SS2 of a semiconductor memory device 100 according to one or more embodiments. FIG. 5 is a perspective view schematically illustrating a portion of a cell array region MCR of the first stack structure SS1. FIG. 6 is a cross-sectional view taken along a line A1-A1′ of FIG. 5. FIG. 7 is a cross-sectional view taken along a line B1-B1′ of FIG. 5. FIG. 8 is a cross-sectional view taken along a line C1-C1′ of FIGS. 3 and 4. FIG. 9 is an enlarged view of a portion CX1 of FIG. 6. FIG. 10 is a layout view illustrating an example of a word line pad WLP included in a semiconductor memory device 100 according to one or more embodiments.

Referring to FIGS. 3 to 10, the semiconductor memory device 100 may include a first stack structure SS1 and a second stack structure SS2, and the second stack structure SS2 may be bonded to the first stack structure SS1 by first and second bonding pads BP1 and BP2.

The first stack structure SS1 may include a first substrate 110. A cell array region MCR and a first scribe lane region SL1 surrounding the cell array region MCR may be defined on the first substrate 110. The first stack structure SS1 may include a plurality of semiconductor patterns 120, a plurality of bit lines BL, a plurality of word lines WL, and a plurality of cell capacitors CAP arranged on the cell array region MCR of the first substrate 110.

A dam structure DS1 may be arranged on the first scribe lane region SL1 of the first substrate 110. In a plan view, the dam structure DS1 may be arranged to surround the cell array region MCR. The dam structure DS1 may function as a protective dam that prevents water or moisture from penetrating into the memory cell array MCA arranged in the cell array region MCR or prevents cracks from penetrating thereinto.

The second stack structure SS2 may include a second substrate 210. A peripheral circuit region PCR and a second scribe lane region SL2 surrounding the peripheral circuit region PCR may be defined on the second substrate 210. The second stack structure SS2 may include a peripheral circuit 220 arranged on the peripheral circuit region PCR of the second substrate 210.

A peripheral circuit dam DS2 may be arranged on the second scribe lane region SL2 of the second substrate 210. The peripheral circuit dam DS2 may be arranged to surround the peripheral circuit region PCR in a plan view. The peripheral circuit dam DS2 may function as a protective dam that prevents water or moisture from penetrating into the peripheral circuit 220 arranged in the peripheral circuit region PCR or prevents cracks from penetrating thereinto. The peripheral circuit dam DS2 may be arranged at a position vertically overlapping the dam structure DS1 included in the first stack structure SS1.

In one or more embodiments, the first substrate 110 may include silicon (Si), germanium (Ge), or silicon germanium (SiGe). In one or more embodiments, the first substrate 110 may include a silicon-on-insulator (SOI) substrate or a germanium-on-insulator (GeOI) substrate.

A plurality of semiconductor patterns 120 may extend in the first horizontal direction X and may be spaced apart from each other in the vertical direction Z on the cell array region MCR of the first substrate 110.

In one or more embodiments, the plurality of semiconductor patterns 120 may include, for example, an undoped semiconductor material or a doped semiconductor material. In one or more embodiments, a plurality of semiconductor patterns 120 may include single crystalline silicon. In one or more embodiments, the plurality of semiconductor patterns 120 may include an amorphous metal oxide, a polycrystalline metal oxide, or a combination of the amorphous metal oxide and the polycrystalline metal oxide, and for example, may include at least one of In—Ga-based oxide (IGO), In—Zn-based oxide (IZO), or In—Ga—Zn-based oxide (IGZO). In some other embodiments, the plurality of semiconductor patterns 120 may include two-dimensional (2D) material semiconductors, for example, the 2D material semiconductor may include MoS₂, WSe₂, graphene, carbon nano tubes, or a combination thereof.

In one or more embodiments, the plurality of semiconductor patterns 120 may have a line shape or a bar shape extending in the first horizontal direction X. In one or more embodiments, each semiconductor pattern 120 may include a channel region 120A, and a first impurity region 120S and a second impurity region 120D arranged in a first horizontal direction X with the channel region 120A therebetween. The first impurity region 120S may be connected to the bit line BL, and the second impurity region 120D may be connected to the cell capacitor CAP. Ohmic metal layers made of metal silicide or the like may be further formed between the first impurity region 120S and the bit line BL and between the second impurity region 120D and the cell capacitor CAP, respectively.

The plurality of word lines WL may be arranged on the top and bottom surfaces of the plurality of semiconductor patterns 120, may be extend in the second horizontal direction Y, and may be spaced apart from each other in the vertical direction Z. One of the plurality of word lines WL may surround the plurality of semiconductor patterns 120 arranged to be spaced apart in the second horizontal direction Y and may extend in the second horizontal direction Y. Among the plurality of word lines WL, two word lines WL spaced apart from each other in the vertical direction Z may be arranged at positions overlapping each other in the vertical direction Z.

In one or more embodiments, the plurality of word lines WL may include at least one of a doped semiconductor material (doped silicon, doped germanium, etc.), a conductive metal nitride (titanium nitride, tantalum nitride, etc.), a metal (tungsten, titanium, tantalum, etc.), and a metal-semiconductor compound (tungsten silicide, cobalt silicide, titanium silicide, etc.).

In one or more embodiments, a gate insulating layer 130 may be arranged between the word line WL and the semiconductor pattern 120. The gate insulating layer 130 may include at least one selected from a high-k dielectric material having a higher dielectric constant than silicon oxide and a ferroelectric material. In one or more embodiments, the gate insulating layer 130 may include at least one selected from hafnium oxide (HfO), hafnium silicate (HfSiO), hafnium oxynitride (HfON), hafnium silicon oxynitride (HfSiON), lanthanum oxide (LaO), lanthanum aluminum oxide (LaAlO), zirconium oxide (ZrO), zirconium silicate (ZrSiO), zirconium oxynitride (ZrON), zirconium silicon oxynitride (ZrSiON), tantalum oxide (TaO), titanium oxide (TiO), barium strontium titanium oxide (BaSrTiO), barium titanium oxide (BaTiO), lead titanate zirconate (PbZrTiO), tantalate strontium bismuth (SrTaBiO), bismuth iron oxide (BiFeO), strontium titanium oxide (SrTiO), yttrium oxide (YO), aluminum oxide (AIO), and lead scandium tantalum oxide (PbScTaO).

A plurality of bit lines BL may extend in the vertical direction Z on the first substrate 110 and may be spaced apart from each other in the second horizontal direction Y. The plurality of bit lines BL may be any one of a doped semiconductor material, a conductive metal nitride, a metal, and a metal-semiconductor compound.

Each cell capacitor CAP may include a first electrode EL1, a capacitor dielectric layer DL, and a second electrode EL2. The first electrode EL1 may extend in the first horizontal direction X and may be spaced apart from each other in the vertical direction Z. The first electrode EL1 may have an inner space extending in the first horizontal direction X, and the inner space may be filled by the capacitor dielectric layer DL and the second electrode EL2. For example, the first electrode EL1 may have a cup shape rotated by 90 degrees.

The capacitor dielectric layer DL may include at least one selected from a high-k dielectric material having a higher dielectric constant than silicon oxide and a ferroelectric material. In one or more embodiments, the capacitor dielectric layer DL may include at least one selected from hafnium oxide (HfO), hafnium silicate (HfSiO), hafnium oxynitride (HfON), hafnium silicon oxynitride (HfSiON), lanthanum oxide (LaO), lanthanum aluminum oxide (LaAlO), zirconium oxide (ZrO), zirconium silicate (ZrSiO), zirconium oxynitride (ZrON), zirconium silicon oxynitride (ZrSiON), tantalum oxide (TaO), titanium oxide (TiO), barium strontium titanium oxide (BaSrTiO), barium titanium oxide (BaTiO), lead titanate zirconate (PbZrTiO), tantalate strontium bismuth (SrTaBiO), bismuth iron oxide (BiFeO), strontium titanium oxide (SrTiO), yttrium oxide (YO), aluminum oxide (AIO), and lead scandium tantalum oxide (PbScTaO).

The second electrode EL2 may fill an inner space of the first electrode EL1, and the capacitor dielectric layer DL may be arranged between the inner space of the first electrode EL1 and the second electrode EL2.

The first electrode EL1 and the second electrode EL2 may include a doped semiconductor material, a conductive metal nitride such as titanium nitride, tantalum nitride, niobium nitride, or tungsten nitride, a metal of ruthenium, iridium, titanium or tantalum, and a conductive metal oxide such as an iridium oxide or niobium oxide.

The plate electrode PP may be arranged to extend in the vertical direction Z and the second horizontal direction Y on one side of the cell capacitor CAP. The second electrode EL2 of the cell capacitor CAP may be electrically connected to the plate electrode PP, and for example, the plate electrode PP may be commonly connected to the plurality of second electrodes EL2 arranged to be spaced apart in the vertical direction Z and the plurality of second electrodes EL2 arranged to be spaced apart in the second horizontal direction Y.

A mold insulating layer 122 may be arranged between two adjacent semiconductor patterns 120 spaced apart from each other in the vertical direction Z, between two adjacent word lines WL spaced apart from each other in the vertical direction Z, and between two adjacent first electrodes EL1 spaced apart from each other in the vertical direction Z. In addition, the mold insulating layer 122 may be arranged between two bit lines BL arranged to be spaced apart in the second horizontal direction Y.

In one or more embodiments, the mold insulating layer 122 may include silicon oxide, silicon oxynitride, silicon nitride, carbon-containing silicon oxide, carbon-containing silicon oxynitride, carbon-containing silicon nitride, or a combination thereof. In one or more embodiments, the mold insulating layer 122 may include a plurality of insulating layers. Here, insulating material layers formed between the plurality of bit lines BL, the plurality of word lines WLs, the plurality of semiconductor patterns 120, and the plurality of cell capacitors CAP may be collectively referred to as the mold insulating layer 122, according to a manufacturing process employed to form a three-dimensional structure.

In one or more embodiments, as illustrated in FIGS. 7 and 10, the word line WL may extend in the second horizontal direction Y to cross the first horizontal direction X, which is the extending direction of the semiconductor pattern 120. A word line pad WLP may be arranged at an end portion of the word line WL. As illustrated in FIG. 10, a plurality of word line pads WLP may be arranged in order in the second horizontal direction Y, and as illustrated in FIG. 7, a plurality of word line pads WLP may be arranged in a stepped form in the second horizontal direction Y.

In one or more embodiments, a word line pad WLP1 connected to an uppermost word line WL, a second word line pad WLP2 connected to the word line WL immediately below the uppermost word line WL, and a third word line pad WLP3 connected to the word line WL arranged under the uppermost two word lines WL are arranged sequentially in the second horizontal direction Y. In this manner, a word line pad WLPn connected to the n-th word line WL from the uppermost portion may be arranged in the second horizontal direction Y.

A cell contact WCT may be arranged on the top surface of each of the word line pads WLP in which the cell contact WCT is a contact 158 connected to the word line pad WLP, and the word line WL may be electrically connected to an upper wiring structure 150 by the cell contact WCT. As the plurality of word line pads WLP are arranged at different vertical levels, the cell contacts WCT connected to the plurality of word line pads WLP may also have heights in different vertical directions.

An upper wiring structure 150 may be arranged on the cell array region MCR. The upper wiring structure 150 may include a wiring layer 152, a via 154, and an insulating layer 156. The upper wiring structure 150 may further include a contact 158 electrically connected to the bit line BL, the word line WL, and the plate electrode PP. In addition, a first bonding pad BP1 arranged coplanar with the uppermost surface of the insulating layer 156 may be formed on the upper wiring structure 150.

The second stack structure SS2 may include a second substrate 210, a peripheral circuit 220 arranged on the second substrate 210, a front wiring structure 230 covering the peripheral circuit 220 on the top surface of the second substrate 210, and a rear wiring structure 240 arranged on the bottom surface of the second substrate 210. The front wiring structure 230 may include a wiring layer 232, a via 234, and an insulating layer 236, and the rear wiring structure 240 may include a wiring layer 242, a via 244, and an insulating layer 246.

The second bonding pad BP2 may have a bottom surface arranged coplanar with the bottom surface of the insulating layer 246, and may be electrically connected to the via 244. As the first bonding pad BP1 and the second bonding pad BP2 are connected to each other, the first stack structure SS1 and the second stack structure SS2 may be bonded to each other. In one or more embodiments, the first stack structure SS1 and the second stack structure SS2 may be attached by a copper-oxide hybrid bonding method. In one or more embodiments, the second bonding pad BP2 and the first bonding pad BP1 may include copper or a copper alloy. An interface between the insulating layer 156 of the upper wiring structure 150 and the insulating layer 246 of the rear wiring structure 240 may extend flat, and may be arranged coplanar with an interface between the second bonding pad BP2 and the first bonding pad BP1.

In one or more embodiments, the peripheral circuit 220 may include a gate electrode 222 and a gate insulating layer 224 arranged on an active region of the second substrate 210. In one or more embodiments, the peripheral circuit 220 may include sense amplifiers, and the sense amplifiers may be electrically connected to the bit lines BL included in the first stack structure SS1. In one or more embodiments, the peripheral circuit 220 may include sub word line drivers, and the sub word line drivers may be electrically connected to the word lines WL included in the first stack structure SS1.

In one or more embodiments, the second stack structure SS2 may further include a through via 250 penetrating the second substrate 210, may electrically connect the wiring layer 232 included in the front wiring structure 230 to the wiring layer 242 included in the rear wiring structure 240 by the through via 250, and the wiring layer 242 included in the rear wiring structure 240 may be electrically connected to the wiring layer 152 included in the upper wiring structure 150 through the second bonding pad BP2 and the first bonding pad BP1.

In one or more embodiments, the first scribe lane region SL1 may be arranged outside the cell array region MCR to surround the cell array region MCR. A dam structure DS1, a dam isolation insulating layer DS10, and a dummy stack DST may be arranged on the first scribe lane region SL1 of the first substrate 110.

In one or more embodiments, a device isolation layer 126 may be arranged at an edge of the cell array region MCR, and a dummy stack DST may be arranged on the first scribe lane region SL1. In a plan view, the dummy stack DST may be arranged on the first scribe lane region SL1 outside the device isolation layer 126.

The dummy stack DST may include a plurality of first semiconductor layers 120R and a plurality of second semiconductor layers 124R alternately stacked on the top surface of the first substrate 110. The dummy stack DST may be a portion of the mold stack MS arranged on the first scribe lane region SL1 among the mold stack MS formed on the first substrate 110 to form the plurality of semiconductor patterns 120, the portion of the mold stack MS remaining without being removed.

In one or more embodiments, the plurality of first semiconductor layers 120R may include the same material as the plurality of semiconductor patterns 120. In one or more embodiments, the plurality of second semiconductor layers 124R may include a single crystal layer of a group IV semiconductor, a group IV-IV compound semiconductor, or a group III-V compound semiconductor.

In one or more embodiments, each of the plurality of first semiconductor layers 120R may be arranged at the same vertical level as the corresponding semiconductor pattern 120 among the plurality of semiconductor patterns 120. In one or more embodiments, each of the plurality of first semiconductor layers 120R may have the same thickness in the vertical direction Z as the corresponding semiconductor pattern 120 among the plurality of semiconductor patterns 120. In other embodiments, each of the plurality of first semiconductor layers 120R is arranged at the same vertical level as the corresponding semiconductor pattern 120 among the plurality of semiconductor patterns 120, but the thickness in the vertical direction Z may be different.

In one or more embodiments, a dam isolation insulating layer DS10 may be arranged in a dam isolation opening DSH penetrating the dummy stack DST. The dam isolation insulating layer DS10 may have a top surface arranged at the same level as the top surface of the dummy stack DST, and a bottom surface of the dam isolation insulating layer DS10 may be connected to the top surface of the first substrate 110. As shown in FIG. 3, in a plan view, the dam isolation insulating layer DS10 may be arranged to surround the cell array region MCR.

In one or more embodiments, the dam structure DS1 may include a dam contact D158, a dam wiring layer D152, and a dam via D154. The dam contact D158 may have a top surface arranged at a higher level than the top surface of the dummy stack DST, and may extend in a vertical direction Z to be connected to the top surface of the first substrate 110. In one or more embodiments, the dam contact D158 may be formed during a process of forming the cell contact WCT and may include the same material as the cell contact WCT. The dam contact D158 may have a top surface arranged at the same level as at least one of the plurality of cell contacts WCT.

In one or more embodiments, the dam wiring layer D152 and the dam via D154 may be simultaneously formed in the process of forming the wiring layer 152 and the via 154 of the upper wiring structure 150. The dam wiring layer D152 and the dam via D154 may be arranged at a position vertically overlapping the dam contact D158.

In one or more embodiments, the dam contact D158 of the dam structure DS1 may extend in the vertical direction Z by penetrating the dam isolation insulating layer DS10. For example, the dam contact D158 may include a first sidewall S_a facing the cell array region MCR and a second sidewall S_b opposite the first sidewall S_a, and the first sidewall S_a and the second sidewall S_b may be in contact with the dam isolation insulating layer DS10.

In one or more embodiments, as the dam contact D158 extends in the vertical direction Z through the dam isolation insulating layer DS10, the dam isolation insulating layer DS10 may be physically separated into two parts. For example, a portion of the dam isolation insulating layer DS10 arranged between the cell array region MCR and the first sidewall S_a of the dam contact D158 may be referred to as the first dam isolation insulating layer DS12, and a portion of the dam isolation insulating layer DS10 arranged on the second sidewall S_b of the dam contact D158 may be referred to as the second dam isolation insulating layer DS14. In other words, the dam isolation insulating layer DS10 may include a first dam isolation insulating layer DS12 and a second dam isolation insulating layer DS14, for example, the first dam isolation insulating layer DS12 may be arranged between the cell array region MCR and the first sidewall S_a of the dam contact D158, and the second dam isolation insulating layer DS14 may be arranged on the second sidewall S_b of the dam contact D158. The first dam isolation insulating layer DS12 and the second dam isolation insulating layer DS14 may be spaced apart from each other with the dam contact D158 therebetween.

A portion of the sidewall of the first dam isolation insulating layer DS12 and a portion of the sidewall of the second dam isolation insulating layer DS14 may be in contact with the dummy stack DST. However, as the first and second sidewalls S_a and S_b of the dam contact D158 are in contact with the first and second dam isolation insulating layers DS12 and DS14, respectively, and are covered by the first and second dam isolation insulating layers DS12 and DS14, the dam contact D158 may not be in direct contact with the dummy stack DST.

In one or more embodiments, the second scribe lane region SL2 may be arranged outside the peripheral circuit region PCR to surround the peripheral circuit region PCR. A peripheral circuit dam DS2 may be arranged on the second scribe lane region SL2 of the second substrate 210.

The peripheral circuit dam DS2 may include a front dam wiring layer D232, a front dam via D234, a rear dam wiring layer D242, a rear dam via D244, and a dam through via D250. In one or more embodiments, the dam through via D250 may penetrate the second scribe lane region SL2 of the second substrate 210 and extend in the vertical direction Z. The front dam wiring layer D232 may be electrically connected to the dam through via D250 through the front dam via D234. The rear dam wiring layer D242 may be electrically connected to the dam through via D250 through the rear dam via D244. In one or more embodiments, the front dam wiring layer D232, the front dam via D234, the rear dam wiring layer D242, the rear dam via D244, and the dam through via D250 may be arranged at positions vertically overlapping the dam structure DS1.

In one or more embodiments, the front dam wiring layer D232 and the front dam via D234 may be formed in the same process as the wiring layer 232 and the via 234 of the front wiring structure 230 and may be covered by an insulating layer 236. The rear dam wiring layer D242 and the rear dam via D244 may be formed in the same process as the wiring layer 242 and the via 244 of the rear wiring structure 240 and may be covered by an insulating layer 246. The dam through via D250 may be formed in the same process as the through via 250 penetrating the second substrate 210.

In one or more embodiments, dam bonding pads DBP1 and DBP2 may be arranged between the peripheral circuit dam DS2 and the dam structure DS1 to electrically connect the peripheral circuit dam DS2 and the dam structure DS1 to each other. In one or more embodiments, the dam bonding pads DBP1 and DBP2 may be arranged at the same vertical level as the first and second bonding pads BP1 and BP2, and may be formed in a process of forming the first and second bonding pads BP1 and BP2.

In general, a mold stack of semiconductor materials is formed to form a three-dimensional DRAM device, and the mold stack is etched in a cell array region to form semiconductor patterns spaced apart from each other in a vertical direction. Since the mold stack of the semiconductor material is formed together on the scribe lane region, the difficulties of the mold stack etching process for forming a dam structure on the scribe lane region may increase.

According to one or more embodiments, in the process of removing a portion of the mold stack on the cell array region MCR and forming the device isolation layer 126, a portion of the mold stack may be removed together on the first scribe lane region SL1 and the dam isolation insulating layer DS10 may be formed, and in the process of forming the cell contact WCT, the dam contact D158 penetrating the dam isolation insulating layer DS10 may be formed. Water and moisture may be prevented from penetrating into the cell array region MCR or cracks may be propagated into the cell array region MCR by the dam structure DS1, so that the semiconductor memory device 100 may have excellent electrical performance. In addition, since the dam isolation insulating layer DS10 and the dam contact D158 may be formed simultaneously in the process of forming the device isolation layer 126 and the cell contact WCT, the difficulties of the manufacturing process of the dam structure DS1 may be reduced.

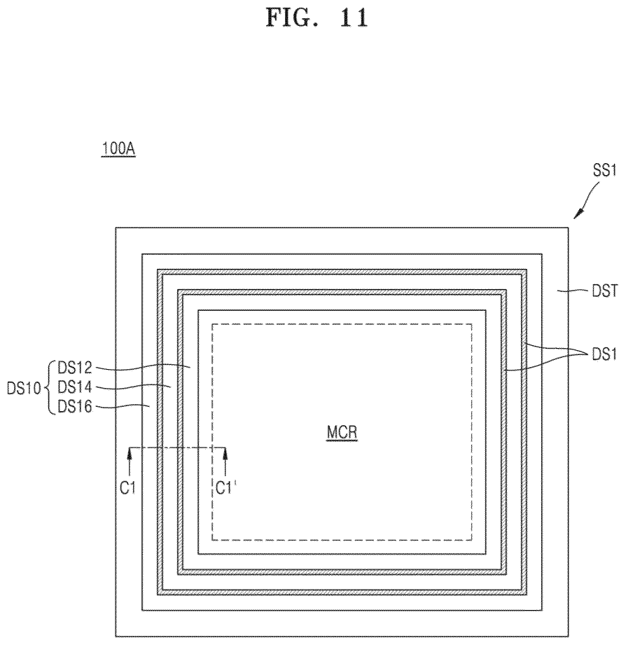

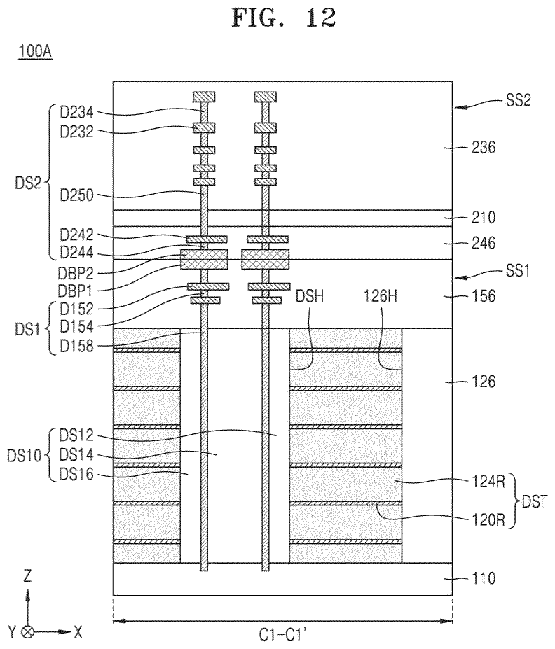

FIG. 11 is a layout view illustrating a semiconductor memory device 100A according to one or more embodiments. FIG. 12 is a cross-sectional view along line C1-C1′ of FIG. 11.

Referring to FIGS. 11 and 12, a plurality of dam structures DS1 and a plurality of peripheral circuit dams DS2 may be formed. For example, as shown in FIGS. 11 and 12, two dam structures DS1 may be spaced apart from each other. For example, the dam isolation insulating layer DS10 may include a first dam isolation insulating layer DS12, a second dam isolation insulating layer DS14, and a third dam isolation insulating layer DS16. One dam structure DS1 may be arranged between the first dam isolation insulating layer DS12 and the second dam isolation insulating layer DS14, and the other dam structure DS1 may be arranged between the second dam isolation insulating layer DS14 and the third dam isolation insulating layer DS16.

In one or more embodiments, as illustrated in FIGS. 11 and 12, two peripheral circuit dams DS2 may be spaced apart from each other, and each of the two peripheral circuit dams DS2 may be arranged to vertically overlap the two dam structures DS1 and may be electrically connected to the two dam structures DS1 through the dam bonding pads DBP1 and DBP2.

According to one or more embodiments, water and moisture may be prevented from penetrating into the cell array region MCR by the dam structure DS1 and the peripheral circuit dam DS2, or cracks may be prevented from being propagated into the cell array region MCR by the dam structure DS1 and the peripheral circuit dam DS2, so that the semiconductor memory device 100A may have excellent electrical performance.

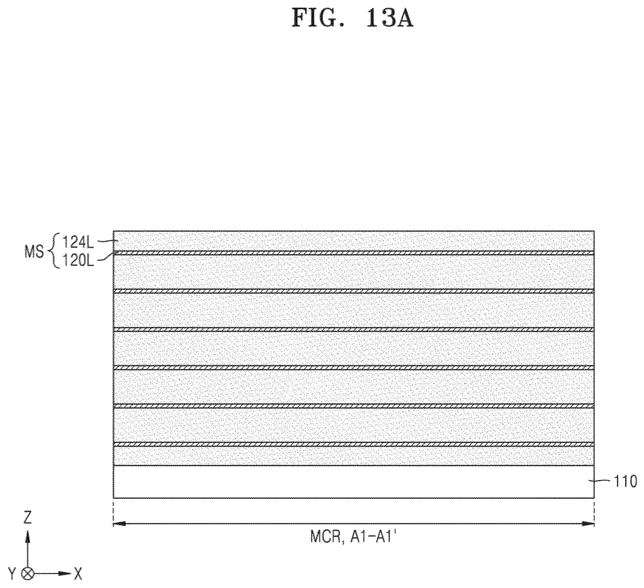

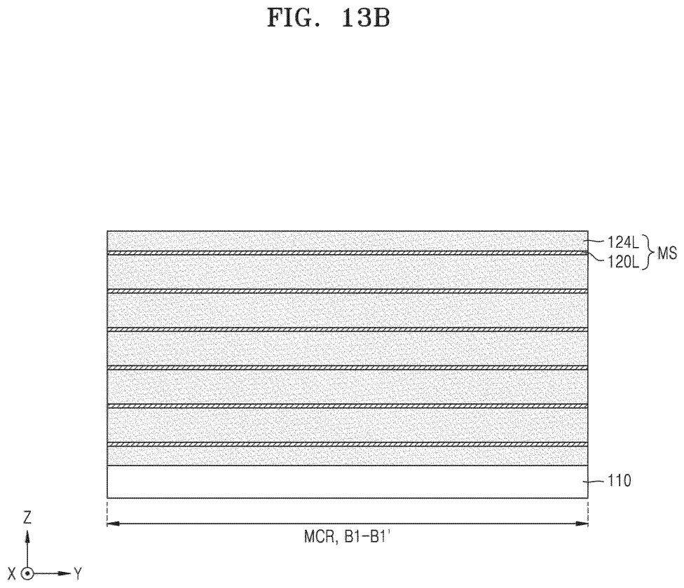

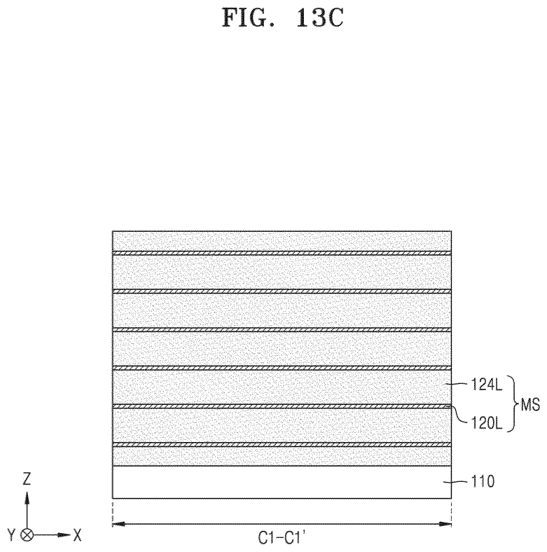

FIGS. 13A, 13B, 13C, 14, 15A, 15B, 15C, 16A, 16B, 17A, 17B, 18, 19, 20A, 20B, 20C, 21A, 21B, and 21C are schematic diagrams illustrating a method of manufacturing a semiconductor memory device 100 according to one or more embodiments.

Referring to FIGS. 13A, 13B and 13C, a mold stack MS may be formed by alternately and sequentially forming a first semiconductor layer 120L and a second semiconductor layer 124L on the first substrate 110. The mold stack MS may be arranged on the cell array region MCR and the first scribe lane region SL1.

In one or more embodiments, the first semiconductor layer 120L and the second semiconductor layer 124L may include a material having etch selectivity with respect to each other. For example, each of the first semiconductor layer 120L and the second semiconductor layer 124L may include a single crystal layer of a group IV semiconductor, a group IV-IV compound semiconductor, or a group III-V compound semiconductor, and the first semiconductor layer 120L and the second semiconductor layer 124L may include different materials. For example, the first semiconductor layer 120L may include single crystal silicon, and the second semiconductor layer 124L may include SiGe. Each of the first semiconductor layer 120L and the second semiconductor layer 124L may have a thickness of several tens of nm.

In one or more embodiments, the first semiconductor layer 120L and the second semiconductor layer 124L may be formed by an epitaxial process. For example, the epitaxy process may be vapor-phase epitaxy (VPE), chemical vapor deposition (CVD) processes such as ultra-high vacuum chemical vapor deposition (UHV-CVD), molecular beam epitaxy, or a combination thereof. In the epitaxy process, a liquid or gaseous precursor may be used as a precursor required to form the first semiconductor layer 120L and the second semiconductor layer 124L.

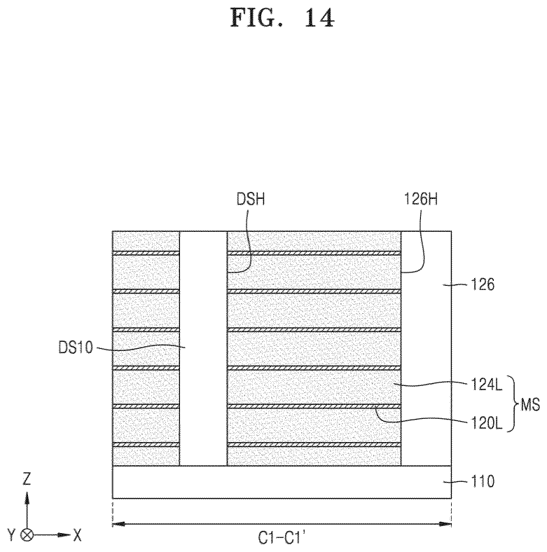

Referring to FIG. 14, a mask pattern may be formed on the mold stack MS, and a portion of the mold stack MS may be removed using the mask pattern as an etching mask to form a device isolation opening 126H and a dam isolation opening DSH.

In one or more embodiments, the device isolation opening 126H may be arranged at an edge portion of each cell array region MCR, and the dam isolation opening DSH may be arranged on the first scribe lane region SL1. In one or more embodiments, in a plan view, the dam isolation opening DSH may be arranged to surround the cell array region MCR.

Thereafter, the device isolation layer 126 and the dam isolation insulating layer DS10 may be formed by using an insulating material in the device isolation opening 126H and the dam isolation opening DSH.

In one or more embodiments, the device isolation layer 126 and the dam isolation insulating layer DS10 may be formed using silicon oxide, silicon nitride, silicon oxynitride, or a combination thereof.

In one or more embodiments, each of the device isolation layer 126 and the dam isolation insulating layer DS10 may have a top surface arranged at the same level as the top surface of the mold stack MS, but is not limited thereto.

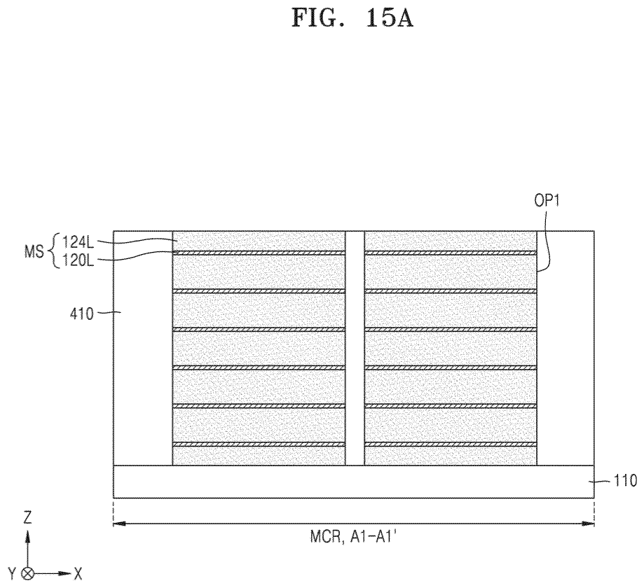

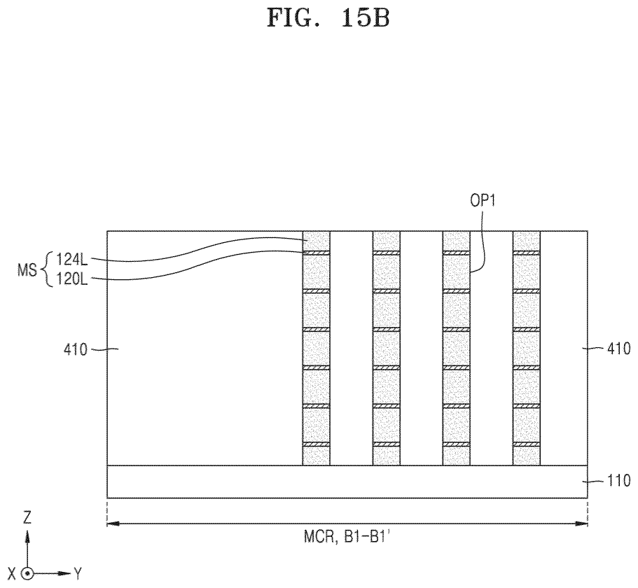

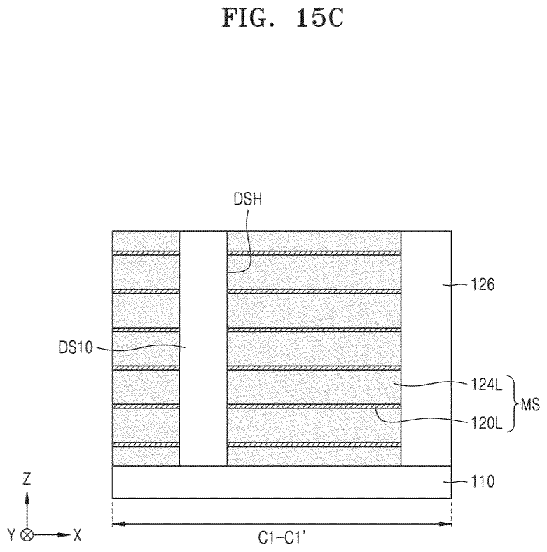

Referring to FIGS. 15A, 15B, and 15C, a mask pattern may be formed on the mold stack MS, and a portion of the mold stack MS may be removed using the mask pattern as an etching mask to form a first opening OP1. Thereafter, a first buried insulating layer 410 may be formed in the first opening OP1.

In one or more embodiments, the plurality of semiconductor patterns 120 may be formed from the first semiconductor layer 120L in the cell array region MCR by forming the first opening OP1. Here, the plurality of semiconductor patterns 120 may be formed by patterning portions of the first semiconductor layer 120L arranged on the cell array region MCR.

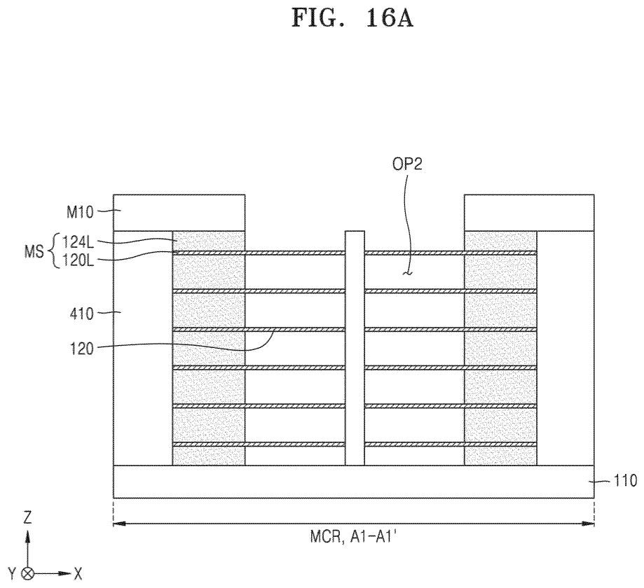

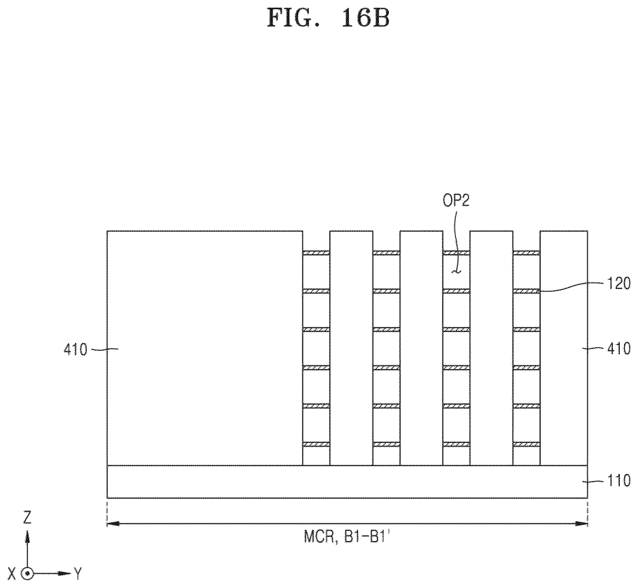

Referring to FIGS. 16A and 16B, a mask pattern M10 may be formed on the mold stack MS of the cell array region MCR, a portion of the second semiconductor layer 124L not covered by the mask pattern M10 may be removed, and some portions of the second semiconductor layer 124L arranged at a position vertically overlapping the mask pattern M10 may remain without being removed.

In one or more embodiments, a process of removing the second semiconductor layer 124L may be a wet etching process or a pull-back process. For example, the process of removing the second semiconductor layer 124L may be an etching process using an etching selectivity between the second semiconductor layer 124L and the first semiconductor layer 120L. For example, in the wet etching process or the pull-back process, the etching rate of the plurality of semiconductor patterns 120 may be relatively low and the etching rate of the second semiconductor layer 124L may be relatively high.

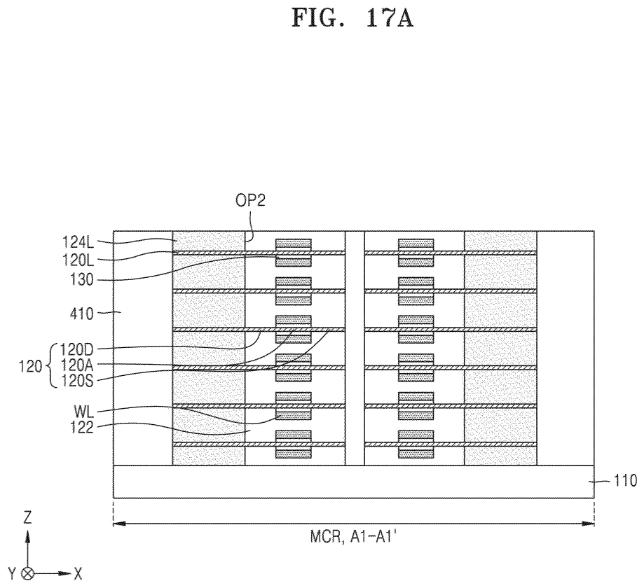

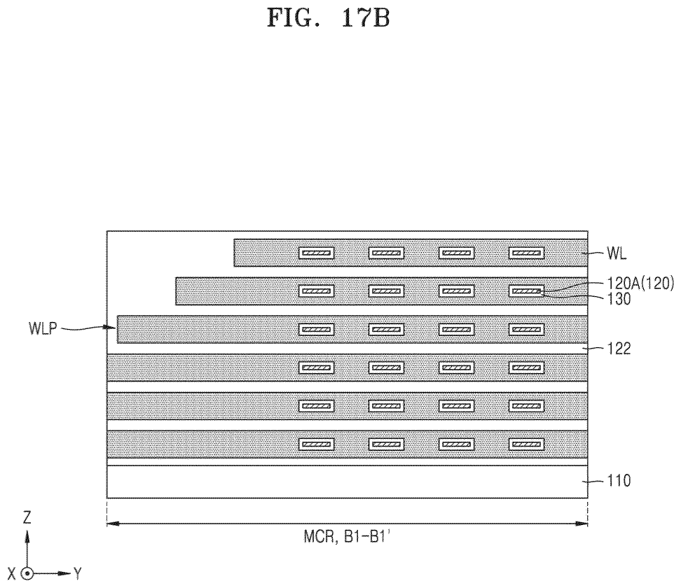

Referring to FIGS. 17A and 17B, a gate insulating layer 130 and a word line WL may be sequentially formed on a top surface, a side surface, and a bottom surface of the plurality of semiconductor patterns 120 in the second opening OP2 in the cell array region MCR. For example, the gate insulating layer 130 may be conformally arranged to surround the plurality of semiconductor patterns 120, and the word line WL may be arranged on the gate insulating layer 130 to surround the plurality of semiconductor patterns 120 and extend in the second horizontal direction Y.

In one or more embodiments, as shown in FIG. 17A, portions of the gate insulating layer 130 and the word line WL arranged at both ends (e.g., both ends in the first horizontal direction X) of the plurality of semiconductor patterns 120 in the second opening OP2 may be removed. In other embodiments, a protective layer covering both ends of the plurality of semiconductor patterns 120 is first formed in the second opening OP2, and then the gate insulating layer 130 and the word line WL surrounding a central portion of the plurality of semiconductor patterns 120 are formed, and then the protective layer is removed, so that both ends of the plurality of semiconductor patterns 120 may be exposed again without being covered by the gate insulating layer 130 and the word line WL.

Thereafter, a mold insulating layer 122 filling the inside of the second opening OP2 may be formed. In one or more embodiments, the mold insulating layer 122 may be arranged between two word lines WL adjacent in the vertical direction Z and between ends of two semiconductor patterns 120 adjacent in the vertical direction Z.

In one or more embodiments, a portion of the word line WL may be removed to form the word line pad WLP. The word line pad WLP may be arranged in a stepwise shape, and for example, the word line pad WLP connected to one word line WL may be spaced apart from a word line pad WLP connected to another word line WL arranged under the one word line WL in the second horizontal direction Y.

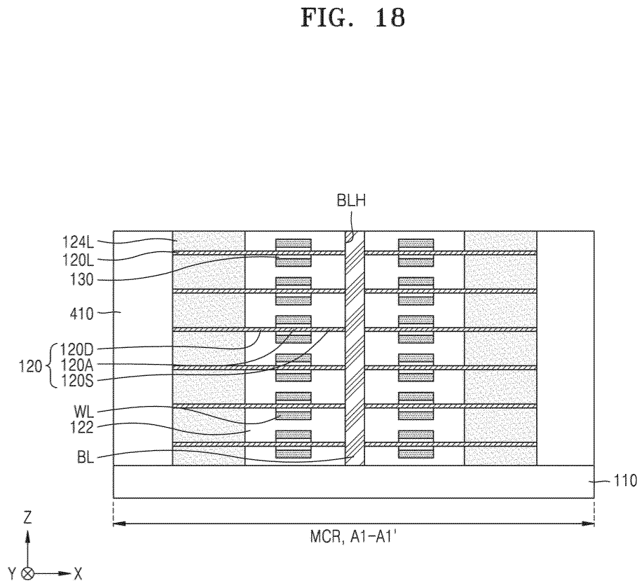

Referring to FIG. 18, a bit line opening BLH may be formed by removing a portion of the buried insulating layer 410 in the cell array region MCR, and a bit line BL may be formed in the bit line opening BLH.

In one or more embodiments, as illustrated in FIG. 18, two semiconductor patterns 120 may be spaced apart from each other in the first horizontal direction X with the bit line BL therebetween, a first sidewall of the bit line BL may be in contact with a first impurity region 120S of one semiconductor pattern 120, and a second sidewall of the bit line BL may be in contact with a first impurity region 120S of another semiconductor pattern 120. That is, two semiconductor patterns 120 arranged at the same vertical level may be electrically connected to one bit line BL, but the technical idea of the disclosure is not limited thereto.

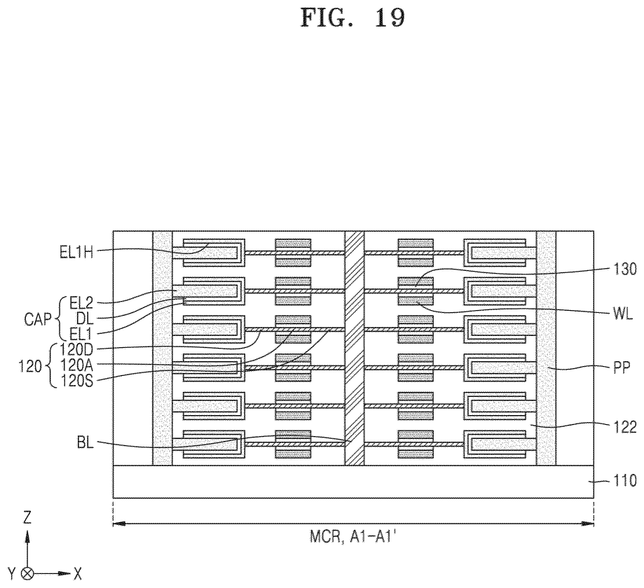

Referring to FIG. 19, the first semiconductor layer 120L and the second semiconductor layer 124L may be removed from the cell array region MCR, and the cell capacitor CAP may be formed at positions where the first semiconductor layer 120L and the second semiconductor layer 124L are removed.

In one or more embodiments, the cell capacitor CAP may include a first electrode EL1, a capacitor dielectric layer DL, and a second electrode EL2. The first electrode EL1 may be electrically connected to the second impurity region 120D of the semiconductor pattern 120 and may have an inner space EL1H extending in the first horizontal direction X. The capacitor dielectric layer DL may be conformally arranged in the inner space EL1H, and the inner space EL1H may be filled by the second electrode EL2.

Thereafter, a plate electrode PP electrically connected to the second electrode EL2 and extending in the second horizontal direction Y may be formed.

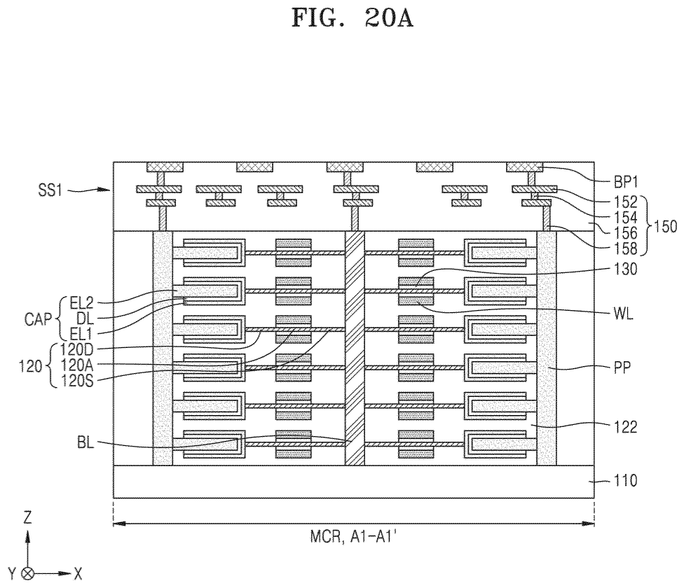

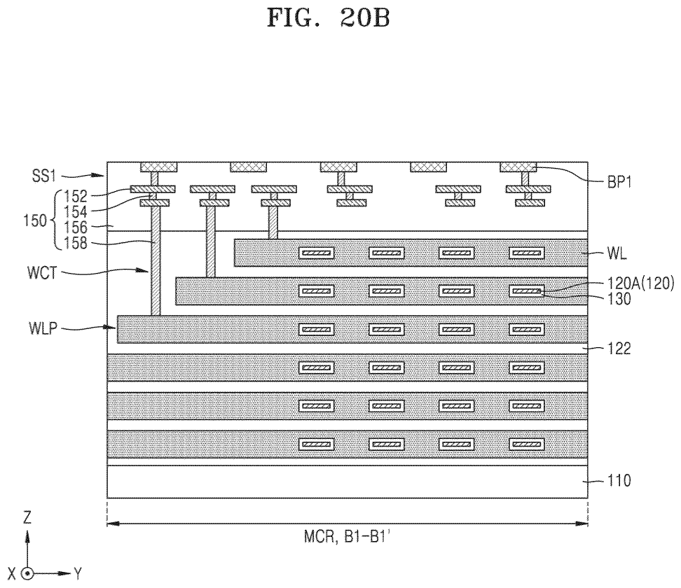

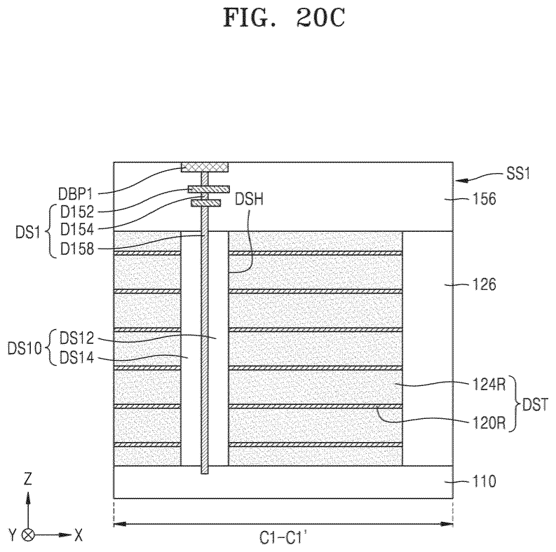

Referring to FIGS. 20A, 20B, and 20C, an upper wiring structure 150 may be formed on the cell array region MCR, and a dam structure DS1 may be formed on the first scribe lane region SL1.

In one or more embodiments, the upper wiring structure 150 may include a wiring layer 152, a via 154, an insulating layer 156, and a contact 158. For example, the contact 158 may be electrically connected to the bit line BL, the word line WL, and the plate electrode PP.

In one or more embodiments, the dam structure DS1 may include a dam contact D158, a dam wiring layer D152, and a dam via D154.

In one or more embodiments, the dam contact D158 may extend in the vertical direction Z through the dam isolation insulating layer DS10. The dam contact D158 may be simultaneously formed in a process for forming any one of the contacts 158, for example, the cell contact WCT. In addition, the dam wiring layer D152 may be formed simultaneously in the process of forming the wiring layer 152, and the dam via D154 may be formed simultaneously in the process of forming the via 154.

In one or more embodiments, the dam contact D158 may be formed to have a height penetrating the mold stack MS or the dummy stack DST, and may have a relatively large aspect ratio. In the etching process for forming the dam contact D158 having a relatively large aspect ratio, the difficulties of the etching process may be relatively reduced because an opening penetrating the dam isolation insulating layer DS10 is formed (for example, compared to a case of a comparative example in which the dummy stack DST is directly etched to form an opening having a large aspect ratio, the difficulties of the etching process of forming an opening penetrating the dam isolation insulating layer DS10 may be lower).

Thereafter, a first bonding pad BP1 and a first dam bonding pad DBP1 arranged on the same plane as the uppermost surface of the insulating layer 156 may be formed on the upper wiring structure 150 and the dam structure DS1.

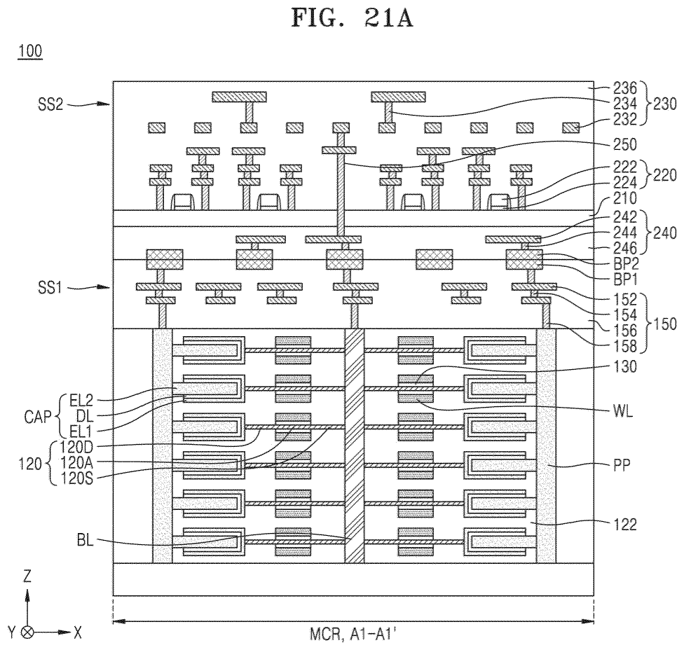

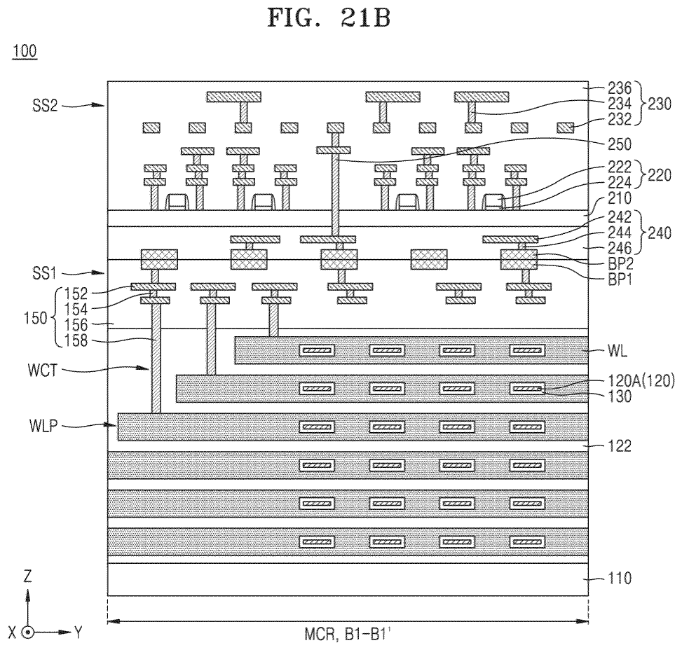

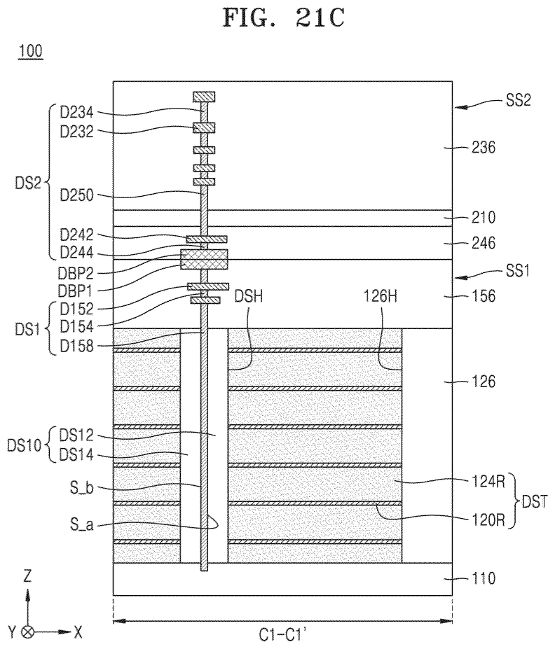

Referring to FIGS. 21A, 21B, and 21C, a second stack structure SS2 may be prepared.

In one or more embodiments, the second stack structure SS2 may include a second substrate 210, and a peripheral circuit region PCR and a second scribe lane region SL2 may be defined in the second substrate 210. A peripheral circuit 220 may be arranged on the peripheral circuit region PCR of the second substrate 210, a front wiring structure 230 covering the peripheral circuit 220 may be arranged on the top surface of the second substrate 210, and a rear wiring structure 240 may be arranged on the bottom surface of the second substrate 210. A peripheral circuit dam DS2 may be arranged on the second scribe lane region SL2 of the second substrate 210.

The peripheral circuit dam DS2 may include a front dam wiring layer D232, a front dam via D234, a rear dam wiring layer D242, a rear dam via D244, and a dam through via D250. The front dam wiring layer D232 and the front dam via D234 may be formed in the same process as the wiring layer 232 and the via 234 of the front wiring structure 230, the rear dam wiring layer D242 and the rear dam via D244 may be formed in the same process as the wiring layer 242 and the via 244 of the rear wiring structure 240, and the dam through via D250 may be formed in the same process as the through via 250 penetrating the second substrate 210.

In one or more embodiments, the peripheral circuit 220 may be formed on a first surface (or top surface) of the second substrate 210, the front wiring structure 230 may be formed on the first surface of the second substrate 210, and a carrier substrate may be attached onto the front wiring structure 230 and then a second surface (or bottom surface) of the second substrate 210 may be ground to thin the second substrate 210. Thereafter, the second stack structure SS2 may be completed by forming the rear wiring structure 240, the second bonding pad BP2, and the second dam bonding pad DBP2 on the second surface of the second substrate 210.

Thereafter, the second stack structure SS2 and the first stack structure SS1 may be bonded to each other, and in this case, the first bonding pad BP1 of the first stack structure SS1 and the second bonding pad BP2 of the second stack structure SS2 may be bonded to each other, and the top surface of the upper insulating layer 156 and the bottom surface of the insulating layer 246 may be bonded to each other. In addition, the first dam bonding pad DBP1 arranged on the first scribe lane region SL1 of the first substrate 110 and the second dam bonding pad DBP2 arranged on the second scribe lane region SL2 of the second substrate 210 may be bonded to each other.

According to one or more embodiments, water and moisture may be prevented from penetrating into the cell array region MCR by the dam structure DS1 and the peripheral circuit dam DS2, or cracks may be prevented from being propagated into the cell array region MCR by the dam structure DS1 and the peripheral circuit dam DS2, so that the semiconductor memory device 100 may have excellent electrical performance. In addition, since the dam isolation insulating layer DS10 and the dam contact D158 may be formed simultaneously in the process of forming the device isolation layer 126 and the cell contact WCT, the difficulties of the manufacturing process of the dam structure DS1 may be reduced.

According to the semiconductor memory device and the manufacturing method thereof, in the process of removing a portion of the mold stack on the cell array region and forming the device isolation layer, a portion of the mold stack may be removed together on the first scribe lane region, and a dam isolation insulating layer may be formed, and in the process of forming the cell contact, a dam contact penetrating the dam isolation insulating layer may be formed. Water and moisture may be prevented from penetrating into the cell array region or cracks may be propagated into the cell array region by the dam structure, so that the semiconductor memory device may have excellent electrical performance. In addition, since the dam isolation insulating layer and the dam contact may be formed simultaneously in the process of forming the device isolation layer and the cell contact, the difficulties of the manufacturing process of the dam structure may be reduced.

While the disclosure has been particularly shown and described with reference to one or more embodiments thereof, it will be understood that various changes in form and details may be made therein without departing from the spirit and scope of the following claims.

What is claimed is:

1. A semiconductor memory device comprising:
a first substrate comprising a cell array region and a first scribe lane region surrounding the cell array region in a plan view;
a memory cell array on the cell array region;
a dam structure on the first scribe lane region, wherein the dam structure surrounds the memory cell array in a plan view and the dam structure comprises a first sidewall facing the memory cell array and a second sidewall opposite the first sidewall;
a first dam isolation insulating layer between the memory cell array and the first sidewall of the dam structure;
a second dam isolation insulating layer on the second sidewall of the dam structure; and
a dummy stack on the first scribe lane region of the first substrate, the dummy stack comprising a plurality of first semiconductor layers and a plurality of second semiconductor layers alternately stacked in a vertical direction.

2. The semiconductor memory device of claim 1,
wherein the memory cell array comprises:
a plurality of semiconductor patterns on the first substrate, wherein the plurality of semiconductor patterns are spaced apart from each other in the vertical direction;
a bit line extending in the vertical direction on the first substrate and commonly connected to a first end of each of the plurality of semiconductor patterns;
a plurality of word lines on the first substrate, wherein the plurality of word lines are spaced apart from each other in the vertical direction, extend in a first horizontal direction, and surround the plurality of semiconductor patterns; and
a plurality of capacitors on the first substrate, wherein the plurality of capacitors are spaced apart from each other in the vertical direction, and are each connected to a second end of the plurality of semiconductor patterns, and
wherein the second end of the plurality of semiconductor patterns is opposite to the first end of the plurality of semiconductor patterns.

3. The semiconductor memory device of claim 2, wherein each of the plurality of semiconductor patterns is at the same vertical level as each of the plurality of first semiconductor layers of the dummy stack.

4. The semiconductor memory device of claim 2,
wherein a top surface of the dam structure is at a vertical level higher than a top surface of an uppermost semiconductor pattern among the plurality of semiconductor patterns, and
wherein a bottom surface of the dam structure is in contact with a top surface of the first substrate.

5. The semiconductor memory device of claim 2, wherein the dam structure further comprises:
a dam contact extending in the vertical direction on a top surface of the first substrate; and
a dam wiring layer on the dam contact.

6. The semiconductor memory device of claim 5,
wherein the memory cell array further comprises:
a plurality of word line pads at respective end portions of the plurality of word lines, the plurality of word line pads having a stepped form; and
a plurality of cell contacts respectively connected to the plurality of word line pads, and
wherein a top surface of at least one of the plurality of cell contacts is at the same vertical level as a top surface of the dam contact.

7. The semiconductor memory device of claim 5,
wherein the first dam isolation insulating layer is on a first sidewall of the dam contact, and
wherein the first sidewall of the dam contact is not in direct contact with the dummy stack.

8. The semiconductor memory device of claim 1, further comprising:
a second substrate at a higher vertical level than the memory cell array, the second substrate comprising a peripheral circuit region and a second scribe lane region surrounding the peripheral circuit region in a plan view;
a peripheral circuit on the peripheral circuit region of the second substrate; and
a peripheral circuit dam on the second scribe lane region of the second substrate and surrounding the peripheral circuit in a plan view.

9. The semiconductor memory device of claim 8, wherein the peripheral circuit dam vertically overlaps the dam structure.

10. The semiconductor memory device of claim 8,
wherein the peripheral circuit dam comprises:
a dam through via in the second scribe lane region of the second substrate;
a front dam wiring layer on a top surface of the second substrate, wherein the front dam wiring layer is connected to the dam through via; and
a rear dam wiring layer on a bottom surface of the second substrate, wherein the rear dam wiring layer is connected to the dam through via, and
wherein the dam through via, the front dam wiring layer, and the rear dam wiring layer vertically overlap each other.

11. A semiconductor memory device comprising:
a memory cell array on a first substrate, the memory cell array comprising:
a plurality of semiconductor patterns on the first substrate, wherein the plurality of semiconductor patterns are spaced apart from each other in a vertical direction,
a bit line extending in the vertical direction on the first substrate and commonly connected to a first end of each of the plurality of semiconductor patterns, and
a plurality of capacitors on the first substrate, wherein the plurality of capacitors are spaced apart from each other in the vertical direction, and are each connected to a second end of the plurality of semiconductor patterns, and wherein the second end of the plurality of semiconductor patterns is opposite to the first end of the plurality of semiconductor patterns;
a dam structure on the first substrate, wherein the dam structure surrounds the memory cell array in a plan view; and
a first dam isolation insulating layer between the memory cell array and the dam structure, wherein the first dam isolation insulating layer surrounds the memory cell array in a plan view.

12. The semiconductor memory device of claim 11,
wherein the dam structure comprises:
a first sidewall facing the memory cell array; and
a second sidewall opposite to the first sidewall, and
wherein the semiconductor memory device further comprises:
a second dam isolation insulating layer on the second sidewall of the dam structure; and
a dummy stack comprising a plurality of first semiconductor layers and a plurality of second semiconductor layers alternately stacked in the vertical direction on the first substrate.

13. The semiconductor memory device of claim 12, wherein the plurality of first semiconductor layers and the plurality of second semiconductor layers are in contact with a sidewall of the second dam isolation insulating layer.

14. The semiconductor memory device of claim 12, wherein the plurality of first semiconductor layers are at the same vertical level as the plurality of semiconductor patterns.

15. The semiconductor memory device of claim 11, further comprising:
a second substrate at a higher vertical level than the memory cell array;
a peripheral circuit on the second substrate; and
a peripheral circuit dam on the second substrate and surrounding the peripheral circuit in a plan view.

16. The semiconductor memory device of claim 15, wherein the peripheral circuit dam vertically overlaps the dam structure.

17. The semiconductor memory device of claim 11,
wherein the memory cell array comprises:
a plurality of word lines on the first substrate, wherein the plurality of word lines are spaced apart from each other in the vertical direction, extend in a first horizontal direction, and surround the plurality of semiconductor patterns;
a plurality of word line pads at respective end portions of the plurality of word lines, the plurality of word line pads having a stepped form; and
a plurality of cell contacts respectively connected to the plurality of word line pads, respectively,
wherein the dam structure comprises:
a dam contact extending in the vertical direction on a top surface of the first substrate; and
a dam wiring layer on the dam contact, and
wherein a top surface of at least one of the plurality of cell contacts is at the same vertical level as a top surface of the dam contact.

18. The semiconductor memory device of claim 17, wherein the top surface of the dam contact is at a higher vertical level than an uppermost semiconductor pattern among the plurality of semiconductor patterns.

19. A semiconductor memory device comprising:
a first substrate comprising a cell array region and a first scribe lane region surrounding the cell array region in a plan view;
a memory cell array on the cell array region, the memory cell array comprising:
a plurality of semiconductor patterns on the first substrate, wherein the plurality of semiconductor patterns are vertically spaced apart from each other;
a bit line extending in a vertical direction on the first substrate and commonly connected to a first end of each of the plurality of semiconductor patterns; and
a plurality of capacitors on the first substrate, wherein the plurality of capacitors are spaced apart in the vertical direction, and are each connected to a second end of the plurality of semiconductor patterns, and wherein the second end of the plurality of semiconductor patterns is opposite to the first end of the plurality of semiconductor patterns;
a dam structure on the first scribe lane region, wherein the dam structure surrounds the memory cell array in a plan view;
a first dam isolation insulating layer between the memory cell array and the dam structure, wherein the first dam isolation insulating layer surrounds the memory cell array in a plan view;
a second substrate at a higher vertical level than the memory cell array;
a peripheral circuit on the second substrate; and
a peripheral circuit dam on the second substrate and surrounding the peripheral circuit in a plan view.

20. The semiconductor memory device of claim 19, further comprising a dummy stack comprising:
a second dam isolation insulating layer on the first scribe lane region and on a sidewall of the dam structure; and
a plurality of first semiconductor layers and a plurality of second semiconductor layers on the first scribe lane region and, wherein the plurality of first semiconductor layers and the plurality of second semiconductor layers are alternately stacked in the vertical direction.
